(19) United States
(12) Patent Application Publication
(10) Pub. No.: US 2026/0075970 A1
(43) Pub. Date: Mar. 12, 2026

(54) PHOTODETECTOR AND DISTANCE MEASUREMENT APPARATUS

(71) Applicant: SONY SEMICONDUCTOR SOLUTIONS CORPORATION, Kanagawa (JP)

(72) Inventors: Hidenobu TSUGAWA, Kanagawa (JP); Ryoichi NAKAMURA, Kanagawa (JP)

(73) Assignee: SONY SEMICONDUCTOR SOLUTIONS CORPORATION, Kanagawa (JP)

(21) Appl. No.: 19/105,116

(22) PCT Filed: Aug. 15, 2023
(86) PCT No.: PCT/JP2023/029493

§ 371 Date: Feb. 20, 2025

(30) Foreign Application Priority Data
Sep. 2, 2022 (JP) 2022-140195

(51) Int. Cl. H10F 39/00; G01S 7/481; G01S 17/08

(52) U.S. Cl. CPC H10F 39/805; G01S 7/4816; G01S 17/08; H10F 39/811

(57) ABSTRACT

A photodetector of an embodiment of the disclosure includes: a first semiconductor substrate having a first surface and a second surface and including a pixel array section; a light-receiving section inside the first semiconductor substrate for each of the pixels that generates carriers corresponding to a received light amount; a multiplication section; an insulating layer stacked on the first surface and having an opening; a polysilicon film with the insulating layer interposed between the first surface and the polysilicon film along at least a border of the pixels that is electrically coupled to the light-receiving section through the opening; a first wiring along an outer shape of each of the pixels on the side of the first surface; and a first connection wiring along the outer shape of each of the pixels on the side of the first surface that electrically couples the polysilicon film and the first wiring.

### TECHNICAL FIELD

The present disclosure relates to a photodetector using, for example, an avalanche photodiode, and to a distance measurement apparatus.

### BACKGROUND ART

In a SPAD array sensor, photons generated when a multiplication section multiplies electrons can enter an adjacent pixel directly or by reflection, and can be erroneously detected in the adjacent pixel. In order to prevent the erroneous detection, for example, PTL 1 discloses a photodetector in which a contact electrode wiring is provided as a light-shielding wall that divides an interlayer insulating film into respective portions corresponding to two adjacent photoelectric converters.

### CITATION LIST

### Patent Literature

PTL 1: International Publication No. WO 2022/131109

### SUMMARY OF THE INVENTION

Incidentally, in a photodetector, it is demanded to improve a pressure resistance performance for miniaturization.

It is desirable to provide a photodetector and a distance measurement apparatus that make it possible to improve a pressure resistance performance against edge breakdown while suppressing crosstalk.

A photodetector of an embodiment of the disclosure includes: a first semiconductor substrate having a first surface and a second surface opposed to each other and including a pixel array section in which a plurality of pixels is arranged in array in an in-plane direction; a light-receiving section that is provided inside the first semiconductor substrate for each of the pixels, and generates carriers corresponding to a received light amount by photoelectric conversion; a multiplication section that is provided on the first surface for each of the pixels, and performs avalanche multiplication of the carriers generated in the light-receiving section; an insulating layer stacked on the first surface, the insulating layer having one or a plurality of openings each provided at a predetermined position; one or a plurality of polysilicon films that is provided on a side of the first surface with the insulating layer interposed between the first surface and the one or the plurality of polysilicon films along at least a border of the pixels that are adjacent to each other, and is electrically coupled to at least the light-receiving section through the one or the plurality of openings; one or a plurality of first wirings provided along an outer shape of each of the pixels on the side of the first surface; and one or a plurality of first connection wirings that is provided along the outer shape of each of the pixels on the side of the first surface, and electrically couples the one or the plurality of polysilicon films and the one or the plurality of first wirings to each other.

A distance measurement apparatus according to an embodiment of the present disclosure includes: an optical system; a photodetector; and a signal processing circuit that calculates a distance to a measurement target from an output signal of the photodetector, and includes, as the photodetector, the photodetector according to an embodiment of the present disclosure.

In the photodetector and the distance measurement apparatus according to the respective embodiments of the present disclosure: the insulating layer having the one or the plurality of openings each provided at the predetermined position and the one or the plurality of polysilicon films that is electrically coupled to the light-receiving section through the one or the plurality of openings of the insulating layer are provided on the side of the first surface of the semiconductor substrate; and the one or the plurality of first connection wirings that electrically couples the one or the plurality of first wirings provided on the side of the first surface of the semiconductor substrate to the light-receiving section is coupled to the one or the plurality of polysilicon films. The one or the plurality of polysilicon films, the one or the plurality of first wirings, and the one or the plurality of first connection wirings have a layout in which they are each formed along at least the border of the adjacent pixels. This prevents penetration of leaked light from adjacent pixels, and ensures a distance between an anode that applies a voltage to the light-receiving section and a cathode that applies a voltage to the multiplication section.

### BRIEF DESCRIPTION OF DRAWINGS

FIG. 1 is a schematic cross-sectional diagram illustrating an example of a configuration of a photodetector according to a first embodiment of the present disclosure.

FIG. 2 is a plan schematic diagram illustrating an example of the configuration of the photodetector illustrated in FIG. 1.

FIG. 3 is a block diagram illustrating an example of a schematic configuration of the photodetector illustrated in FIG. 1.

FIG. 4 is an example of an equivalent circuit diagram of a unit pixel of the photodetector illustrated in FIG. 1.

FIG. 5 is a plan schematic diagram illustrating another example of the configuration of the photodetector illustrated in FIG. 1.

FIG. 6 is a schematic cross-sectional diagram illustrating an example of a configuration of a photodetector according to a modification example of the present disclosure.

FIG. 7 is a schematic cross-sectional diagram illustrating an example of a configuration of a photodetector according to a second embodiment of the present disclosure.

FIG. 8 is an example of an equivalent circuit diagram of a unit pixel of the photodetector illustrated in FIG. 7.

FIG. 9 is a schematic cross-sectional diagram illustrating an example of a configuration of a photodetector according to a third embodiment of the present disclosure.

FIG. 10 is a plan schematic diagram illustrating an example of the configuration of the photodetector illustrated in FIG. 9.

FIG. 11 is a functional block diagram illustrating an example of an electronic apparatus using the photodetector illustrated in FIG. 1 or other drawings.

FIG. 12A is a schematic diagram illustrating an example of an overall configuration of a photodetection system using the photodetector illustrated in FIG. 1.

FIG. 12B is a diagram illustrating an example of a circuit configuration of the photodetection system illustrated in FIG. 12A.

FIG. 13 is a block diagram depicting an example of schematic configuration of a vehicle control system.

FIG. 14 is a diagram of assistance in explaining an example of installation positions of an outside-vehicle information detecting section and an imaging section.

### MODES FOR CARRYING OUT THE INVENTION

In the following, description is given of embodiments of the present disclosure in detail with reference to the drawings. The following description is merely a specific example of the present disclosure, and the present disclosure should not be limited to the following aspects. Moreover, the present disclosure is not limited to arrangements, dimensions, dimensional ratios, and the like of each component illustrated in the drawings. It is to be noted that the description is given in the following order.

### 1. First Embodiment

(Photodetector in which connection wiring serving as light shield and provided in periphery of pixel is electrically coupled to anode through polysilicon film)

### 2. Modification Example (Another Example of Configuration of Photodetector)

### 3. Second Embodiment

(Photodetector in which readout circuit is provided on substrate separate from light-receiving element and is stacked)

### 4. Third Embodiment

(Photodetector in which another connection wiring different from connection wiring serving as light shield and provided in periphery of pixel is provided, and is directly coupled to anode)

### 5. Application Examples

### 6. Practical Application Example

### 1. First Embodiment

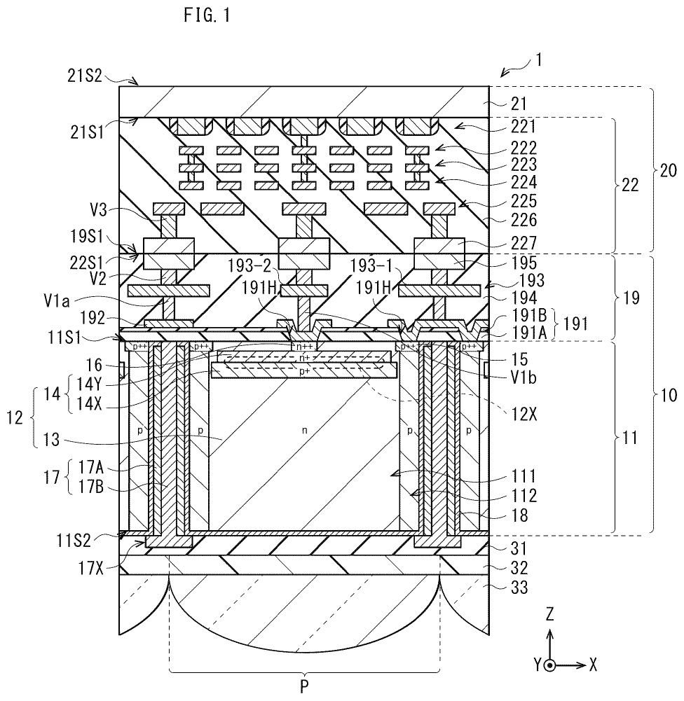

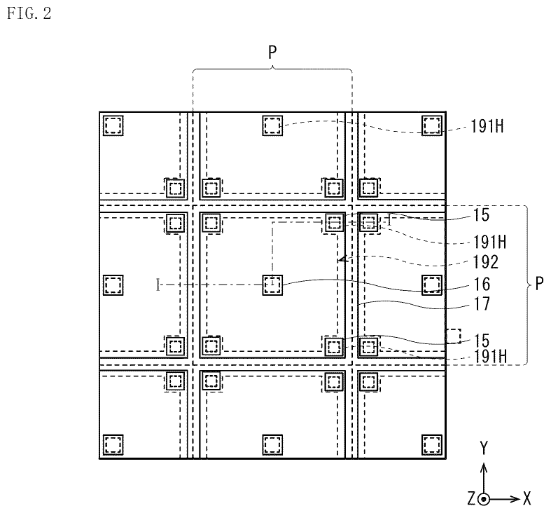

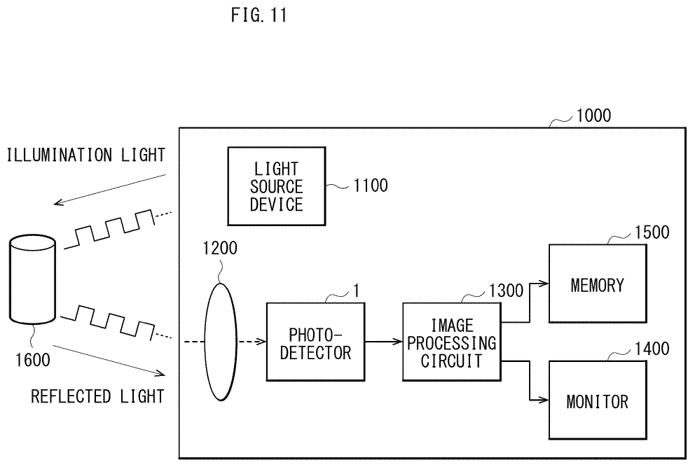

FIG. 1 is schematically illustrates an example of a cross-sectional configuration of a photodetector (a photodetector 1) according to a first embodiment of the present disclosure. FIG. 2 schematically illustrates an example of a planar configuration of the photodetector 1 illustrated in FIG. 1, and FIG. 1 illustrates a cross section corresponding to a line I-I illustrated in FIG. 2. The photodetector 1 is applied to, for example, a distance image sensor (a distance image apparatus 1000 described later; see FIG. 11) that performs distance measurement by a ToF (Time-of-Flight) method, an image sensor, or the like.

### 1-1. Schematic Configuration of Photodetector

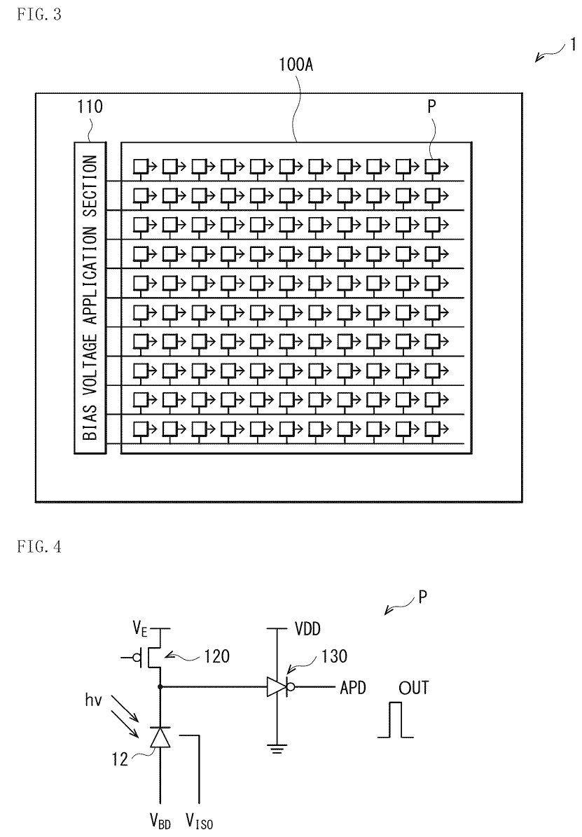

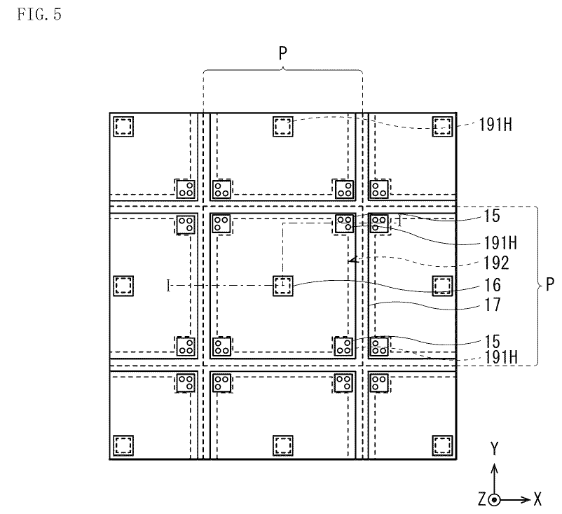

FIG. 3 is a block diagram illustrating a schematic configuration of the photodetector 1 illustrated in FIG. 1, and FIG. 4 illustrates an example of an equivalent circuit of a unit pixel P of the photodetector 1 illustrated in FIG. 1. The photodetector 1 includes, for example, a pixel array section 100A in which a plurality of unit pixels P is arranged in a row direction and in a column direction. As illustrated in FIG. 3, the photodetector 1 includes a bias voltage application section 110 together with the pixel array section 100A. The bias voltage application section 110 applies a bias voltage to each of the unit pixels P in the pixel array section 100A. In the present embodiment, description is given of a case where electrons are read as signal charge.

As illustrated in FIG. 3, the unit pixel P includes a light-receiving element 12, a quenching resistance element 120 including a p-type MOSFET (Metal-Oxide-Semiconductor Field-Effect Transistor), and an inverter 130 including, for example, a complementary type MOSFET.

The light-receiving element 12 converts incident light into an electric signal by photoelectric conversion, and outputs the converted electric signal. The light-receiving element 12 collaterally converts the incident light (photon) into the electric signal by photoelectric conversion, and outputs a pulse corresponding to the incidence of the photon. The light-receiving element 12 is, for example, an SPAD (Single Photon Avalanche Diode) element. The SPAD element has, for example, a characteristic in which an avalanche multiplication region 12X (a depletion layer) is formed by a large negative voltage applied to a cathode, and electrons generated in response to the incidence of one photon cause avalanche multiplication and a large current flows. The light-receiving element 12 has, for example, an anode coupled to the bias voltage application section 110 and the cathode coupled to a source terminal of the quenching resistance element 120. A device voltage VED is applied from the bias voltage application section 110 to the anode of the light-receiving element 12.

The quenching resistance element 120 is coupled in series to the light-receiving element 12, and has the source terminal coupled to the cathode of the light-receiving element 12 and a drain terminal coupled to an unillustrated power supply. An excitation voltage VE is applied from the power supply to the drain terminal of the quenching resistance element 120. When a voltage of electrons having been subjected to the avalanche multiplication by the light-receiving element 12 reaches a negative voltage VBD, the quenching resistance element 120 performs quenching in which the electrons multiplied by the light-receiving element 12 are emitted to return the voltage to an initial voltage.

The inverter 130 has an input terminal coupled to the cathode of the light-receiving element 12 and to the source terminal of the quenching resistance element 120, and an output terminal coupled to an unillustrated subsequent arithmetic processing section. The inverter 130 outputs a light-receiving signal on the basis of the carriers (signal charge) multiplied by the light-receiving element 12. More specifically, the inverter 130 shapes the voltage generated by the electrons multiplied by the light-receiving element 12. The inverter 130 then outputs a light-receiving signal (APD OUT) in which a pulse waveform illustrated in FIG. 4 is generated, for example, with an arrival time of one font as a starting point, to the arithmetic processing section. For example, the arithmetic processing section performs arithmetic processing for determining a distance to a subject on the basis of a timing at which the pulse indicating the arrival time of one font is generated in each light-receiving signal, and determines the distance for each of the unit pixels P. On the basis of the distances, a distance image is then generated in which the distances to the subject detected by the plurality of unit pixels P are arranged in a planar manner.

### 1-1. Cross-Sectional Configuration of Photodetector

The photodetector 1 is, for example, what is called a back side illumination photodetector in which a logic substrate 20 is stacked on a side of a front surface of a sensor substrate 10 (e.g., a side of a front surface (a first surface 11S1) of a semiconductor substrate 11 constituting the sensor substrate 10), and receives light from a side of a back surface of the sensor substrate 10 (e.g., a back surface (a second surface 11S2) of the semiconductor substrate 11 constituting the sensor substrate 10).

In the photodetector 1, the sensor substrate 10 and the logic substrate 20 are stacked, as described above. The sensor substrate 10 includes, for example, the semiconductor substrate 11 configured by a silicon substrate, and a multilayer wiring layer 19 provided on the side of the first surface 11S1 of the semiconductor substrate 11. A light-receiving section 13 and a multiplication section 14 constituting the light-receiving element 12, for example, are formed to be embedded in the semiconductor substrate 11 for each of the unit pixels P. The semiconductor substrate 11 further includes a pixel separation section 17 that electrically separates adjacent unit pixels P from each other. The pixel separation section 17 is provided between the plurality of unit pixels P adjacent to each other in the row direction and the column direction to extend from the first surface 11S1 to the second surface 11S2 of the semiconductor substrate 11. The pixel separation section 17 is provided in a lattice pattern in a plan view in the entire pixel array section 100A. The semiconductor substrate 11 further includes a contact layer 15 (anode) electrically coupled to the light-receiving section 13, and a contact layer 16 (cathode) electrically coupled to the multiplication section 14.

The photodetector 1 of the present embodiment has a configuration in which the contact layer 15 and a wiring (a wiring 193-1) are electrically coupled to each other through a polysilicon film 192 and a via Vla. The wiring 193-1 is one wiring included in a wiring layer 193 provided inside the multilayer wiring layer 19 that is provided on the first surface 11S1 of the semiconductor substrate 11. The polysilicon film 192, the wiring 193-1, and the via V1a are each formed continuously so as to surround the light-receiving element 12 in a plan view, along a border of unit pixels P that are adjacent to each other. A gate insulating layer 191 is provided between the first surface 11S1 of the semiconductor substrate 11 and the polysilicon film 192. The polysilicon film 192 is electrically coupled to the contact layer 15 through an opening 191H formed in the gate insulating layer 191.

It is to be noted that the symbols “p” and “n” in the diagram represent a p type semiconductor region and an n type semiconductor region, respectively. Further, “+” and “−” at the end of “p” each represent an impurity concentration of the p type semiconductor region. Likewise, “+” and “−” at the end of “n” each represent an impurity concentration of the n type semiconductor region. Here, larger numbers of “+” indicate higher impurity concentration, and larger numbers of “−” indicate lower impurity concentration. The same applies to the following drawings.

The semiconductor substrate 11 has the first surface 11S1 and the second surface 11S2 opposed to each other. The semiconductor substrate 11 includes, for example, a p-well (p) common to the plurality of unit pixels P. The semiconductor substrate 11 is provided, for each of the unit pixels P, with an n-type semiconductor region (n) 111 in which an impurity concentration is controlled to an n-type, for example, that constitutes the light-receiving section 13. The semiconductor substrate 11 is further provided with a p-type semiconductor region (p⁺) 14X and an n-type semiconductor region (n⁺) 14Y that constitute the multiplication section 14 on the side of the first surface 11S1. This allows for formation of the light-receiving element 12 for each of the unit pixels P. The pixel separation section 17 that electrically separates the adjacent unit pixels P from each other is provided in the periphery of the unit pixel P. A p-type semiconductor region (p) 112 having a higher impurity concentration than that of the p-well is provided between the light-receiving element 12 and the pixel separation section 17.

The light-receiving element 12 has a multiplication region (the avalanche multiplication region 12X) that performs avalanche multiplication of carriers by a high electric field region. As described above, the light-receiving element 12 is the SPAD element that enables the formation of the avalanche multiplication region 12X by a large negative voltage applied to the cathode (the contact layer 16) and that enables the avalanche multiplication of electrons generated by the incidence of one photon.

The light-receiving section 13 corresponds to a specific example of a “light-receiving section” of the present disclosure. The light-receiving section 13 has a photoelectric conversion function of absorbing light incident from the side of the second surface 11S2 of the semiconductor substrate 11 and generating carriers corresponding to the received light amount. As described above, the light-receiving section 13 includes the n-type semiconductor region (n) 111 of which an impurity concentration is controlled to an n-type, and carriers (electrons) generated by the light-receiving section 13 are transferred to the multiplication section 14 by a potential gradient.

The multiplication section 14 corresponds to a specific example of a “multiplication section” of the present disclosure. The multiplication section 14 performs avalanche multiplication of carriers (here, electrons) generated by the light-receiving section 13. The multiplication section 14 is configured by, for example, the p-type semiconductor region (p⁺) 14X having an impurity concentration higher than that of the p-well (p), and the n-type semiconductor region (n⁺) 14Y having an impurity concentration higher than that of the n-type semiconductor region (n) 111. The p-type semiconductor region (p⁺) 14X and the n-type semiconductor region (n⁺) 14Y are provided on the side of the first surface 11S1. The n-type semiconductor region (n⁺) 14Y and the p-type semiconductor region (p⁺) 14X are formed to be stacked in this order from the side of the first surface 11S1.

An area of the p-type semiconductor region (p⁺) 14X and an area of the n-type semiconductor region (n⁺) 14Y are substantially the same as each other in an X-Y plane direction. However, the present disclosure is not limited thereto, and the area of the n-type semiconductor region (n⁺) 14Y in the X-Y plane direction may be smaller than the area of the p-type semiconductor region (p⁺) 14X in the X-Y plane direction, or the area of the p-type semiconductor region (p⁺) 14X in the X-Y plane direction may larger than the area of the n-type semiconductor region (n⁺) 14Y in the X-Y plane direction and may be provided across the entire surface of the unit pixel P partitioned by the pixel separation section 17, for example.

In the light-receiving element 12, the avalanche multiplication region 12X is formed at a junction part between the p-type semiconductor region (p⁺) 14X and the n-type semiconductor region (n⁺) 14Y. The avalanche multiplication region 12X is a high electric field region (a depletion layer) formed at an interface between the p-type semiconductor region (p⁺) 14X and the n-type semiconductor region (n⁺) 14Y by a large negative voltage applied to the cathode. In the avalanche multiplication region 12X, electrons (e⁻) generated by one photon incident on the light-receiving element 12 are multiplied.

The first surface 11S1 of the semiconductor substrate 11 is further provided with the contact layer 15 and the contact layer 16. The contact layer 15 includes a p-type semiconductor region (p⁺⁻) electrically coupled to the n-type semiconductor region (n) 111 constituting the light-receiving section 13. The contact layer 16 includes an n-type semiconductor region (n⁺⁺) electrically coupled to the n-type semiconductor region (n⁺) 14Y constituting the multiplication section 14.

As illustrated in FIG. 2, for example, the contact layer 15 is provided at each of four corners, for example, of the unit pixel P having a shape in the X-Y plane direction of substantially rectangle, and is coupled to the bias voltage application section 110 as the anode of the light-receiving element 12. As illustrated in FIG. 2, for example, one contact layer 16 is provided at an approximate center of the unit pixel P, and is coupled as the cathode of the light-receiving element 12 to the source terminal of the quenching resistance element 120.

The pixel separation section 17 electrically separates adjacent unit pixels P from each other, and is provided in a lattice pattern, for example, in a plan view to partition the plurality of unit pixels P from each other in the pixel array section 100A. The pixel separation section 17 extends from the first surface 11S1 to the second surface 11S2 of the semiconductor substrate 11, and penetrates the semiconductor substrate 11, for example. The pixel separation section 17 is configured by, for example, an insulating film 17A and a light-shielding film 17B embedded in the insulating film 17A. The pixel separation section 17 may be provided from the side of the second surface 11S2 of the semiconductor substrate 11. However, the present disclosure is not limited thereto, and the pixel separation section 17 may be formed from the side of the first surface 11S1 of the semiconductor substrate 11.

The insulating film 17A is formed using, for example, silicon oxide (SiOₓ) or the like. The light-shielding film 17B is formed using, for example, a metal material having a light-shielding property, such as tungsten (W), aluminum (Al), copper (Cu), cobalt (Co), nickel (Ni), or titanium (Ti), or a silicon compound thereof. In addition thereto, the light-shielding film 17B may be formed using polysilicon (Poly-Si). The light-shielding film 17B may be provided with an increased width section 17X formed to be extended on the second surface 11S2 of the semiconductor substrate 11, for the purpose of suppressing incidence of oblique incident light between adjacent unit pixels P.

A side surface and a bottom surface of the pixel separation section 17 and the second surface 11S2 of the semiconductor substrate 11 may be provided with, for example, a layer having fixed electric charge (a fixed charge film 18). The fixed charge film 18 may be a film having positive fixed electric charge or a film having negative fixed electric charge.

It is preferable to use, as a constituent material of the fixed charge film 18, a semiconductor material or electrically-conductive material having a wider band gap than that of the semiconductor substrate 11 for the formation. This makes it possible to suppress generation of a dark current at the interface of the semiconductor substrate 11. Examples of the constituent material of the fixed charge film 18 include hafnium oxide (HfOₓ), aluminum oxide (AlOₓ), zirconium oxide (ZrOₓ), tantalum oxide (TaOₓ), titanium oxide (TiOₓ), lanthanum oxide (LaOₓ), praseodymium oxide (PrOₓ), cerium oxide (CeOₓ), neodymium oxide (NdOₓ), promethium oxide (PmOₓ), samarium oxide (SmOₓ), europium oxide (EuOₓ), gadolinium oxide (GdOₓ), terbium oxide (TbOₓ), dysprosium oxide (DyOₓ), holmium oxide (HoOₓ), thulium oxide (TmOₓ), ytterbium oxide (YbOₓ), lutetium oxide (LuOₓ), yttrium oxide (YOₓ), hafnium nitride (HfNₓ), aluminum nitride (AlNₓ), hafnium oxynitride (HfOₓN_{y}), and aluminum oxynitride (AlOₓN_{y}).

The semiconductor substrate 11 further includes a readout circuit that outputs a pixel signal based on electric charge outputted from the unit pixel P.

In the multilayer wiring layer 19, the gate insulating layer 191 and an interlayer insulating layer 194 are stacked in this order from the side of the first surface 11S1 of the semiconductor substrate 11.

The gate insulating layer 191 corresponds to a specific example of an “insulating layer” of the present disclosure. The gate insulating layer 191 includes, for example, a stacked film of an insulating film 191A and an insulating film 191B, and is formed on the first surface 11S1 of the semiconductor substrate 11. The gate insulating layer 191 has, at a predetermined position, one or a plurality of openings 191H at which the first surface 11S1 is exposed. Specifically, as illustrated in FIG. 2, the one or the plurality of openings 191H is provided on each of the contact layer 15 that is provided at each of the four corners of the unit pixel P, and the contact layer 16 provided at the approximate center of the unit pixel P. The gate insulating layer 191 may be formed using, for example, silicon oxide (SiOₓ), TEOS, silicon nitride (SiNₓ), silicon oxynitride (SiOₓN_{y}), or the like. For example, the insulating film 191A includes a silicon oxide film, and the insulating film 191B includes a silicon nitride film.

The interlayer insulating layer 194 is provided with a plurality of polysilicon films 192, one or a plurality of wiring layers (e.g., the wiring layer 193), a plurality of pad electrodes 195, and a plurality of vias (e.g., the via V1a, a via V1b, and a via V2), each as a transmission path for supplying a voltage to be applied to the semiconductor substrate 11 or the light-receiving element 12 or for extracting carriers generated by the light-receiving element 12, for example.

The plurality of polysilicon films 192 corresponds to a specific example of “one or a plurality of polysilicon films” of the present disclosure. Each of the plurality of polysilicon films 192 is provided on the gate insulating layer 191, and is electrically coupled to corresponding one of the contact layers 15 and 16 through the opening 191H provided on the corresponding one of the contact layers 15 and 16. The plurality of polysilicon films 192 may be formed using polysilicon (Poly-Si); however, the present disclosure is not limited thereto. The plurality of polysilicon films 192 may include any material that is configured to have a selective ratio with the insulating films included in the gate insulating layer 191 at a time of performing etching processing, and examples thereof include a refractory metal such as tungsten (W) or nickel (Ni), a barrier metal such as titanium nitride (TiN) or tantalum nitride (TaN), and a silicide such as nickel silicide (NiSi) or cobalt silicide (CoSi).

The wiring layer 193 includes the wiring 193-1 corresponding to a “first wiring” of the present disclosure and a wiring 193-2 corresponding to a “second wiring” of the present disclosure, and is provided in the interlayer insulating layer 194. The wiring layer 193 is formed using, for example, aluminum (Al), copper (Cu), tungsten (W), or the like. It is to be noted that FIG. 1 illustrates an example in which one wiring layer 193 is formed in the multilayer wiring layer 19; however, the total number of wiring layers in the multilayer wiring layer 19 is not limited, and two or more wiring layers may be formed.

The plurality of pad electrodes 195 is used for coupling with the logic substrate 20, and is embedded in a front surface (a front surface 19S1 of the multilayer wiring layer 19), of the interlayer insulating layer 194, on a side opposite to the side of the semiconductor substrate 11. The plurality of pad electrodes 195 is formed using copper (Cu), for example.

The via V1a corresponds to a specific example of “one or a plurality of first connection wirings” of the present disclosure, and electrically couples a portion of the wiring (the wiring 193-1) of the wiring layer 193 to the polysilicon film 192 that is electrically coupled to the contact layer 15. The via V1b corresponds to a specific example of a “second connection wiring” of the present disclosure, and electrically couples a portion of the wiring (the wiring 193-2) of the wirings of the wiring layer 193 to the polysilicon film 192 that is electrically coupled to the contact layer 16. The via V2 electrically couples the plurality of wirings that configures the wiring layer 193 to the plurality of pad electrodes 195. The vias V1a, V1b, and V2 are formed using, for example, a metal material having a light-shielding property, such as tungsten (W), aluminum (Al), copper (Cu), cobalt (Co), nickel (Ni), or titanium (Ti), or a silicon compound thereof.

As illustrated in FIGS. 1 and 2, the polysilicon film 192, a portion of the wiring (the wiring 193-1) in the wiring layer 193, and the via V1a are each formed continuously along a border of adjacent pixels so as to surround the periphery of the light-receiving element 12 in a plan view. This makes it possible to prevent penetration of the photons generated when carriers (here, electrons) are multiplied by the multiplication section 14 into adjacent unit pixels P by the photon being reflected between the first surface 11S1 of the semiconductor substrate 11 and the wiring layer 193. Further, the application of the device voltage VBD to the light-receiving section 13 is performed through the opening 191H provided at each of the four corners, so that it is possible to ensure a distance between the anode and the cathode.

It is to be noted that, in FIG. 2, the contact layer 15 formed at each of the four corners of the unit pixel P and the polysilicon film 192 are coupled to each other by one opening 191H; however, the present disclosure is not limited thereto. The contact layer 15 and the polysilicon film 192 may be coupled to each other through a plurality of openings 191H, for example, as illustrated in FIG. 5. Further, for example, the via V1a may not necessarily be formed continuously along an outer shape of the unit pixel P (for example, the border of adjacent unit pixels P), for example, a plurality of vias V1a each having a pillar shape may be provided along the outer shape of the unit pixel P.

The logic substrate 20 includes, for example, a semiconductor substrate 21 configured by a silicon substrate, and a multilayer wiring layer 22. The semiconductor substrate 21 has a first surface 21S1 and a second surface 21S2 that are opposed to each other, and formed on the first surface 21S1 is a logic circuit that includes, for example: the above-described bias voltage application section 110 including a cathode voltage generation circuit 51, an anode voltage generation circuit 52, and modulation voltage generation circuits 53A and 53B; a vertical drive circuit; a column signal processing circuit; a horizontal drive circuit; an output circuit; and the like.

In the multilayer wiring layer 22, for example, a gate wiring 221 of a transistor constituting the logic circuit and wiring layers 222, 223, 224, and 225 each including one or a plurality of wirings are stacked in order from a side of the semiconductor substrate 21 with an interlayer insulating layer 226 interposed therebetween. A plurality of pad electrodes 227 is embedded in a front surface, of the interlayer insulating layer 226 (a front surface 22S1 of the multilayer wiring layer 22), on a side opposite to the side of the semiconductor substrate 21. The plurality of pad electrodes 227 is electrically coupled to a portion of the wiring of the wiring layer 225 through a via V3.

In the same manner as the interlayer insulating layer 194, the interlayer insulating layer 117 is configured by, for example, a monolayer film including one of silicon oxide (SiOₓ), TEOS, silicon nitride (SiNₓ), silicon oxynitride (SiOₓN_{y}), or the like, or a stacked film including two or more thereof.

In the same manner as the wiring layer 193, the gate wiring 221 and the wiring layers 222, 223, 224, and 225 are formed using, for example, aluminum (Al), copper (Cu), tungsten (W), or the like.

The pad electrode 227 is exposed on a bonded surface with the sensor substrate 10 (the front surface 22S1 of the multilayer wiring layer 22), and is used, for example, to be coupled to the sensor substrate 10. In the same manner as the pad electrode 195, the pad electrode 227 is formed using, for example, copper (Cu).

In the photodetector 1, for example, Cu—Cu bonding is made between the pad electrode 195 and the pad electrode 227. This allows the cathode of the light-receiving element 12 to be electrically coupled to the quenching resistance element 120 provided on a side of the logic substrate 20, and the anode of the light-receiving element 12 is electrically coupled to the bias voltage application section 110.

On a side of a light-receiving surface (the second surface 11S2) of the semiconductor substrate 11, for example, a microlens 33 is provided for each of the unit pixels P with a protective layer 31 and a color filter 32 being interposed therebetween.

The microlens 33 condenses light incident from above to the light-receiving element 12, and is formed using, for example, silicon oxide (SiOₓ), or the like.

### Workings and Effects

In the photodetector 1 of the present embodiment, the gate insulating layer 191 having the opening 191H at each of four corners of the unit pixel P and the polysilicon film 192 in which the opening 191H is embedded are provided on the side of the first surface 11S1 of the semiconductor substrate 11, and the via V1a that electrically couples the wiring 193-1 provided on the side of the first surface 11S1 of the semiconductor substrate 11 to the light-receiving section 13 is coupled to the polysilicon film 192. The polysilicon film 192, the via V1a, and the wiring 193-1 are each formed continuously along the border of adjacent unit pixels P so as to surround the light-receiving element 12. This prevents penetration of leaked light from adjacent unit pixels P, and ensures the distance between the anode (the contact layer 15) that applies a voltage to the light-receiving section 13 and the cathode (the contact layer 16) that applies a voltage to the multiplication section 14. This is described below.

In the technology of the SPAD, a high bias voltage is applied to multiply carriers generated by photoelectric conversion of incident light, thereby enabling extraction thereof as a large signal.

In such a photodetector in which the SPAD elements are arranged in array, photons generated when one SPAD element multiplies carriers (e.g., electrons) may enter another SPAD element that is adjacent thereto (referred to as adjacent element) directly or by reflection, and may be erroneously detected in the adjacent element by photoelectric conversion and multiplication. This is called crosstalk.

As a method of preventing the erroneous detection, a photodetector described above has been proposed in which a contact electrode wiring having a linear shape coupled to an anode or a cathode is provided as a light-shielding wall that divides an interlayer insulating film into respective portions corresponding to two adjacent photoelectric converters.

However, in a photodetector in which a contact electrode wiring is provided in a linear shape so as to surround a photoelectric converter, a shortest distance between an anode and a cathode is as short as approximately one-half of a pixel pitch. For example, in a photodetector that applies a voltage of higher than or equal to 10 V, pressure resistance can be insufficient.

In contrast, in the present embodiment, the wiring 193-1 and the connection wiring V1a are provided in the multilayer wiring layer 19 that is provided on the side of the first surface 11S1 of the semiconductor substrate 11. The wiring 193-1 and the connection wiring V1a are continuous along the outer shape of the unit pixel P (for example, the border of adjacent unit pixels P) so as to surround the periphery of the light-receiving element 12. The connection wiring V1a electrically couples the wiring 193-1 and the contact layer 15 serving as the anode to each other. In addition, the gate insulating layer 191 and the polysilicon film 192 are provided in the multilayer wiring layer 19. The gate insulating layer 191 is provided on the first surface 11S1 of the semiconductor substrate 11, and has the opening 191H on the contact layer 15. The polysilicon film 192 is continuous along the border of adjacent unit pixels P so as to surround the periphery of the light-receiving element 12, as with the wiring 193-1 and the connection wiring V1a, and embeds the opening 191H to thereby be in contact with the contact layer 15. The connection wiring V1a is electrically coupled to the contact layer 15 through the polysilicon film 192. Thus, the penetration of the leaked light from adjacent pixels is prevented by the polysilicon film 192, the via V1a, and the wiring 193-1. Moreover, the distance between the anode (the contact layer 15) and the cathode (the contact layer 16) in the unit pixel P is a distance from the four corners of the rectangular unit pixel P to the approximate center, i.e., approximately 12 times the pixel pitch.

As described above, it is possible for the photodetector 1 of the present embodiment to improve a pressure resistance performance against the edge breakdown while suppressing the crosstalk. This facilitates miniaturization of the unit pixel P that configures the photodetector 1.

Next, description is given of second and third embodiments and modification examples of the present disclosure as well as application examples and practical application example. Hereinafter, components similar to those of the foregoing first embodiment are denoted by the same reference numerals, and descriptions thereof are omitted as appropriate.

### 2. Modification Examples

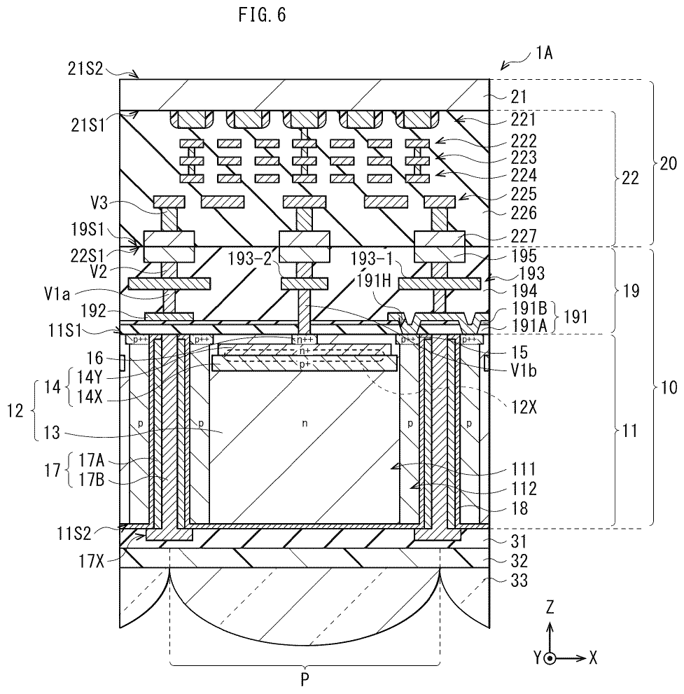

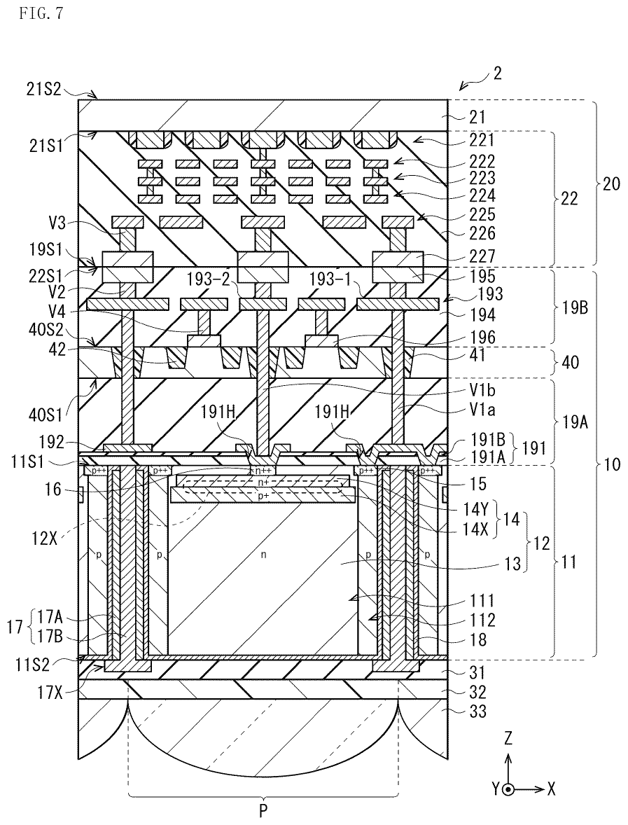

FIG. 6 schematically illustrates an example of a cross-sectional configuration of a photodetector (a photodetector 1A) according to a modification example of the present disclosure. In the same manner as the foregoing first embodiment, for example, the photodetector 1A is applied to a distance image sensor (the distance image apparatus 1000 described later) that performs distance measurement by the ToF method, an image sensor, or the like.

In the first embodiment, the description has been given of the example in which the contact layer 16 provided as the cathode at the approximate center of the unit pixel P and the via V1b are electrically coupled to each other through the polysilicon film 192; however, the present disclosure is not limited thereto. As illustrated in FIG. 6, the contact layer 16 and the via V1b may be directly coupled to each other.

This makes it possible to establish the connection without increasing a resistance value between the contact layer 16 and the via V1b.

### 3. Second Embodiment

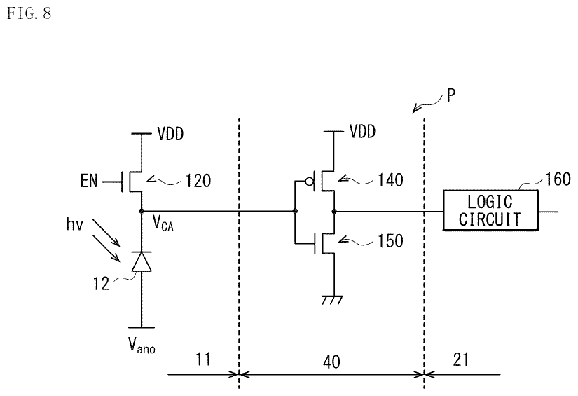

FIG. 7 schematically illustrates an example of a cross-sectional configuration of a photodetector (a photodetector 2) according to a modification example of the present disclosure. FIG. 8 illustrates an example of an equivalent circuit of a unit pixel P of the photodetector 2 illustrated in FIG. 7. In the same manner as the foregoing first embodiment, for example, the photodetector 2 is applied to a distance image sensor (the distance image apparatus 1000 described later) that performs distance measurement by the ToF method, an image sensor, or the like.

In the photodetector 2 of the present embodiment, a readout circuit that outputs a pixel signal based on electric charge outputted from the unit pixel P is provided in a semiconductor substrate (a semiconductor layer 40) that is different from the semiconductor substrate 11 in which the light-receiving element 12 is provided, and the semiconductor layer 40 is disposed between the semiconductor substrate 11 and the semiconductor substrate 21.

The semiconductor layer 40 corresponds to a specific example of a “second semiconductor substrate” of the present disclosure. The semiconductor layer 40 is a semiconductor layer including, for example, silicon, and has a first surface 40S1 and a second surface 40S2 opposed to each other. The first surface 40S1 of the semiconductor layer 40 is opposed to the first surface 11S1 of the semiconductor substrate 11 with the multilayer wiring layer 19A interposed therebetween, and the second surface 40S2 of the semiconductor layer 40 is opposed to the first surface 21S1 of the semiconductor substrate 21 with the multilayer wiring layer 19B and the multilayer wiring layer 22 interposed therebetween. A portion of a plurality of transistors included in the readout circuit is provided on the second surface 40S2 of the semiconductor layer 40. For example, in the readout circuit, a quench circuit including the quenching resistance element 120 is provided on the side of the semiconductor substrate 11. For example, a pulse shaping circuit including an inverter circuit that includes a P type MOS transistor 140 and an N type MOS transistor 150 is provided on the semiconductor layer 40. The semiconductor layer 40 is further provided with a separation section 41 that separates the semiconductor layer 40 for each unit pixel P, for example, and an element separation region 42 that electrically separates the transistors from each other.

In the photodetector 2, the wiring layer 193 described above is provided inside the layer of the multilayer wiring layer 19B provided on the side of the second surface 40S2 of the semiconductor layer 40. The via V1a that electrically couples the wiring 193-1 to the contact layer 15 and the via V1b that electrically couples the wiring 193-2 to the contact layer 16 each penetrate the semiconductor layer 40. In detail, the vias V1a and V1b each penetrate the separation section 41 that separates the semiconductor layer 40. Thus, the semiconductor layer 40 is electrically insulated from the vias V1a and V1b.

As described above, in the present embodiment, a portion of the readout circuit is provided in the semiconductor layer 40, and the semiconductor layer 40 is stacked to form a three-dimensional structure. This makes it possible to reduce a footprint of the readout circuit as compared with the above-described first embodiment. It is also possible to simplify a wiring structure of the wiring layer to be provided in the multilayer wiring layer 19, and to reduce a wiring capacity. In addition, it is possible to reduce power consumption.

Further, it is possible for the present technology to achieve a great effect in a photodetector having a three-dimensional structure, as with the present embodiment. For example, in the case where the semiconductor layer 40 having a large refractive index difference is disposed on the side of the first surface 11S1 of the semiconductor substrate 11 as with the present embodiment, a path through which photons leak to adjacent unit pixels P becomes complicated and the number of paths is increased due to an increase in an area of the reflective surface. However, in the photodetector 2 of the present embodiment, the via V1a that electrically couples the wiring 193-1 and the contact layer 15 to each other penetrates the semiconductor layer 40, which makes it possible to prevent the penetration of the photons reflected by the first surface 40S1 of the semiconductor layer 40 to adjacent unit pixels P. This makes it possible to achieve further miniaturization of the photodetector.

### 4. Third Embodiment

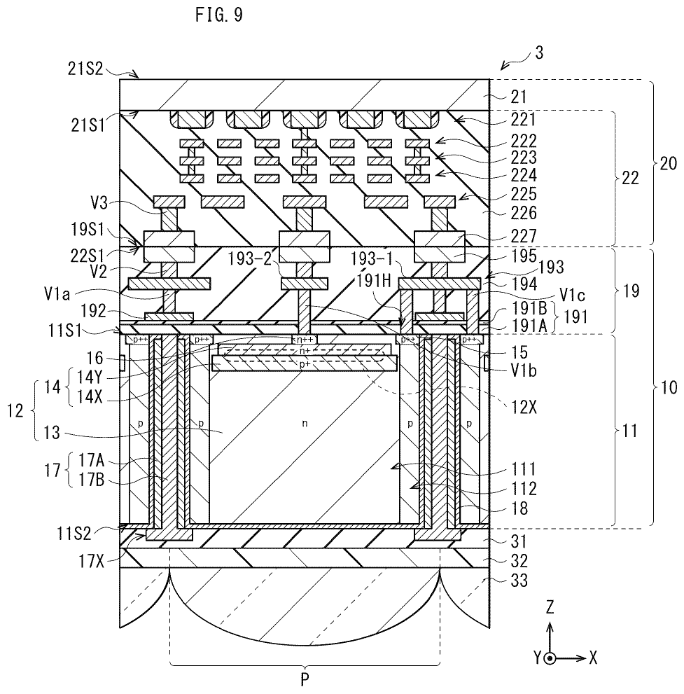

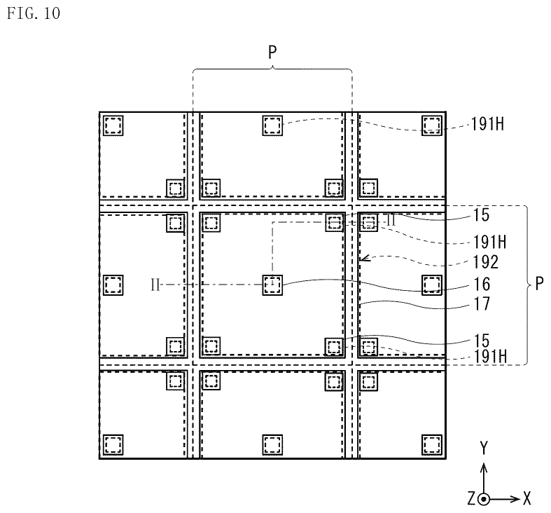

FIG. 9 schematically illustrates an example of a cross-sectional configuration of a photodetector (a photodetector 3) according to a third embodiment of the present disclosure. FIG. 10 schematically illustrates an example of a planar configuration of the photodetector 3 illustrated in FIG. 9. In the same manner as the foregoing first embodiment, for example, the photodetector 3 is applied to a distance image sensor (the distance image apparatus 1000 described later) that performs distance measurement by the ToF method, an image sensor, or the like.

In above first embodiment, the description has been given of the example in which the contact layer 15 serving as the anode and the via V1a are electrically coupled to each other through the polysilicon film 192; however, for example, the polysilicon film 192 may be provided only on the pixel separation section 17, and the polysilicon film 192 and the wiring 193-1 may be coupled to each other through the via via V1a, whereas the wiring 193-1 and the contact layer 15 may be coupled to each other without through the polysilicon film 192, but through a via V1c that penetrates the gate insulating layer 191.

This makes it possible to select whether or not the via V1 is in direct contact with the semiconductor substrate 11 depending on the presence or absence of the polysilicon film 192 while achieving advantages similar to those of the above-described first embodiment.

### 5. Application Examples

### Application Example 1

FIG. 11 illustrates an example of a schematic configuration of a distance image apparatus 1000 as an electronic apparatus including the photodetector (e.g., the photodetector 1) according to the foregoing first to third embodiments and modification examples. The distance image apparatus 1000 corresponds to a specific example of a “distance measurement apparatus” of the present disclosure.

The distance image apparatus 1000 includes, for example, a light source device 1100, an optical system 1200, the photodetector 1, an image processing circuit 1300, a monitor 1400, and a memory 1500.

The distance image apparatus 1000 receives light (modulated light or pulse light) projected from the light source device 1100 toward an irradiation target 1600 and reflected by a surface of the irradiation target 1600, thereby acquiring a distance image corresponding to a distance to the irradiation target 1600.

The optical system 1200 includes one or a plurality of lenses, and guides image light (incident light) from the irradiation target 1600 to the photodetector 1 to form an image on a light-receiving surface (a sensor unit) of the photodetector 1.

The image processing circuit 1300 performs image processing for constructing the distance image on the basis of a distance signal supplied from the photodetector 1, and the distance image (image data) obtained by the image processing is supplied to the monitor 1400 and displayed, or is supplied to the memory 1500 and stored (recorded).

In the distance image apparatus 1000 configured as described above, application of the above-described photodetector (e.g., the photodetector 1) makes it possible to calculate the distance to the irradiation target 1600 only on the basis of the light-receiving signal from the highly stable unit pixel P, and to generate a highly accurate distance image. That is, the distance image apparatus 1000 is able to acquire a more accurate distance image.

### Application Example 2

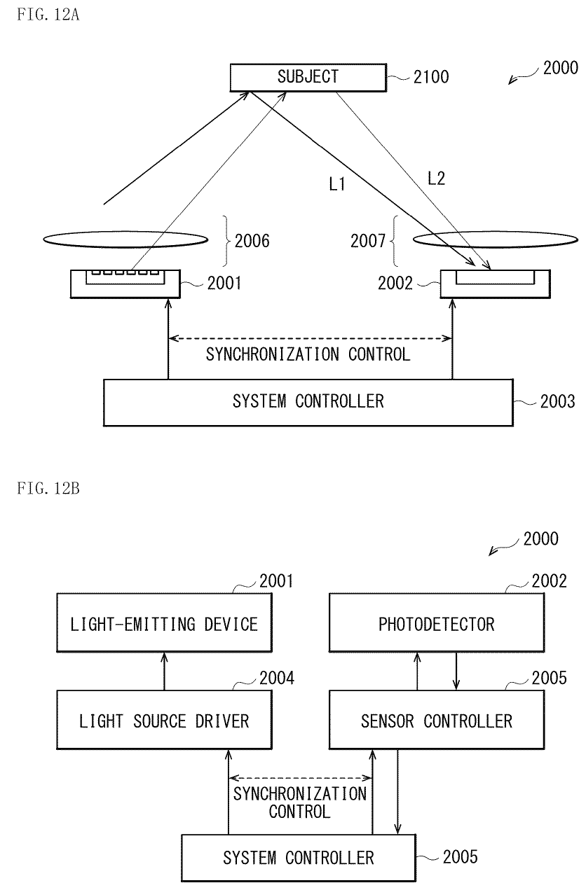

FIG. 12A schematically illustrates an example of an overall configuration of a photodetection system 2000 including a photodetector (e.g., the photodetector 1). FIG. 12B illustrates an example of a circuit configuration of the photodetection system 2000. The photodetection system 2000 includes a light-emitting device 2001 as a light source section that emits infrared light L2 and a photodetector 2002 as a light-receiving section. As photodetector 2002, the photodetector 1 described above may be used, for example. The photodetection system 2000 may further include a system controller 2003, a light source driver 2004, a sensor controller 2005, a light source-side optical system 2006, and a camera-side optical system 2007.

The photodetector 2002 is configured to detect light L1 and light L2. The light L1 is light in which ambient light from an outside is reflected by a subject (a measurement target 2100 (FIG. 12A). The light L2 is light that is emitted by the light-emitting device 2001 and thereafter reflected by the subject 2100. The light L1 is, for example, visible light, and the light L2 is, for example, infrared light. The light L1 is detectable by a photoelectric converter in the photodetector 2002 and the light L2 is detectable in a photoelectric conversion region in the photodetector 2002. It is possible to acquire image information of the subject 2100 from the light L1, and to acquire distance information between the subject 2100 and the photodetection system 2000 from the light L2. The photodetection system 2000 is mountable on an electronic apparatus such as a smartphone or a mobile body such as a car. The light-emitting device 2001 is configurable, for example, with a semiconductor laser, a surface-emitting semiconductor laser, or a vertical-cavity surface-emitting laser (VCSEL). As a method of detecting, by the photodetector 2002, the light L2 emitted from the light-emitting device 2001, an iTOF method may be employed for example; however, the present disclosure is not limited thereto. In the iTOF method, the photoelectric converter is configured to measure a distance to the subject 2100 by, for example, optical time-of-flight (Time-of-Flight; TOF). As a method of detecting, by the photodetector 2002, the light L2 emitted from the light-emitting device 2001, a structured light method or a stereo vision method may be employed, for example. For example, in the structured light method, the measurement of the distance between the photodetection system 2000 and the subject 2100 may be enabled by projecting light of a pattern that is set in advance on the subject 2100 and analyzing a distortion degree of the pattern. Further, in the stereo vision method, the measurement of the distance between the photodetection system 2000 and the subject 2100 may be enabled by, for example, acquiring two or more images viewed from two or more different viewpoints of the subject 2100 with use of two or more cameras. It is to be noted that it is possible to perform synchronization control on the light-emitting device 2001 and the photodetector 2002 by the system controller 2003.

### 6. Practical Application Example

### Example of Practical Application to Mobile Body

The technology according to the present disclosure is applicable to a variety of products. For example, the technology according to the present disclosure may be achieved as a device mounted on any type of mobile body such as a vehicle, an electric vehicle, a hybrid electric vehicle, a motorcycle, a bicycle, a personal mobility, an airplane, a drone, a vessel, a robot, a construction machine, or an agricultural machine (tractor).

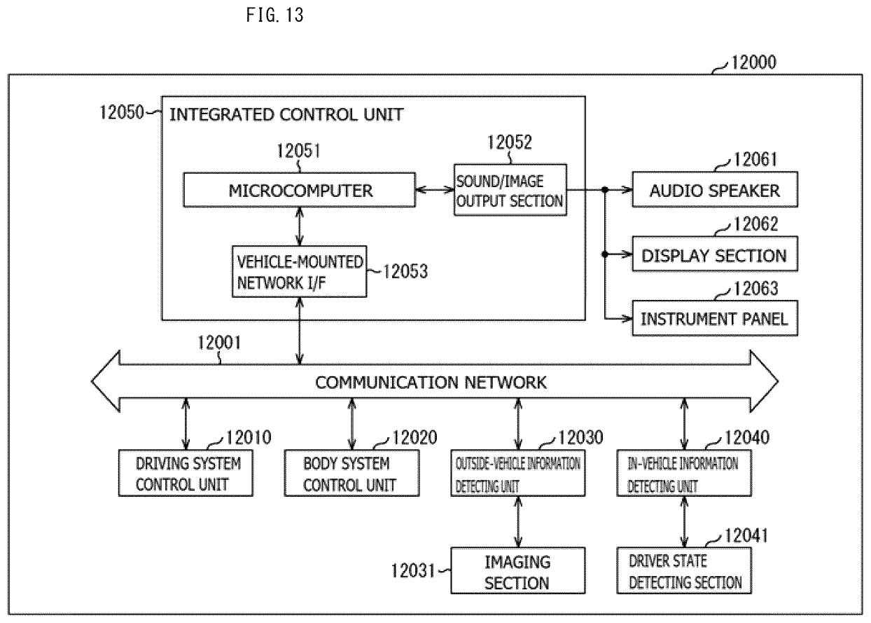

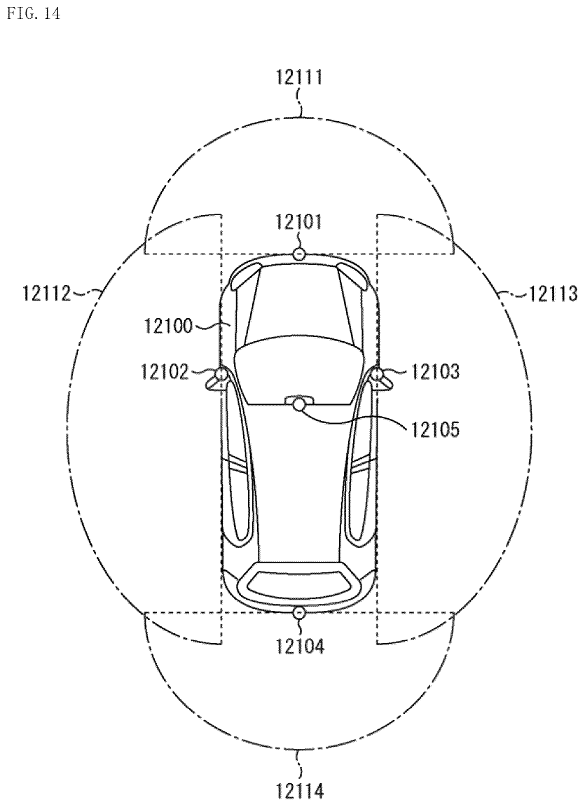

FIG. 13 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 13, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 13, an audio speaker 12061, a display section 12062, and an instrument panel 12063 are illustrated as the output device. The display section 12062 may, for example, include at least one of an on-board display and a head-up display.

FIG. 14 is a diagram depicting an example of the installation position of the imaging section 12031.

In FIG. 14, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 14 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

Although the description has been given with reference to the first to third embodiments, the modification example, the application examples, and the practical application example, the contents of the present disclosure are not limited to the above-described embodiments and the like. For example, in the above embodiments and the like, the present technology is described using the unit pixel P having the rectangular shape; however, the shape of the unit pixel P is not limited to the rectangular shape. For example, the unit pixel P may have a polygonal shape such as an octagonal shape. In this case, it is possible to achieve similar effects by providing the contact layer 15 and the opening 191H that electrically couples the contact layer 15 to the polysilicon film 192 at each of the corners.

Further, the photodetector of the present disclosure does not have to include all of the components described in the above embodiments and the like, and may include other layers. For example, in a case where the photodetector 1 is to detect light other than visible light (e.g., near-infrared light (IR)), the color filter 32 may be omitted.

In addition, a polarity of the semiconductor region constituting the photodetector according to the present disclosure may be inverted. Moreover, in the photodetector according to the present disclosure, holes may serve as the signal charge.

Further, as long as the photodetector according to the present disclosure is in a state in which the avalanche multiplication occurs by applying a reverse-bias between the anode and the cathode, the respective potentials are not limited.

In addition, the above embodiment and the like exemplify the semiconductor substrate 11 including silicon; however, the semiconductor substrate 11 may include, for example, germanium (Ge), or a compound semiconductor (e.g., silicon germanium (SiGe)) of silicon (Si) and germanium (Ge).

It should be appreciated that the effects described herein are mere examples. The disclosure may include any effects other than those described herein, or may further include other effects in addition to those described herein.

It is to be noted that the present disclosure may have the following configurations. According to the present technology having the following configurations, it is possible to prevent penetration of leaked light from adjacent pixels, and to ensure a distance between an anode that applies a voltage to a light-receiving section and a cathode that applies a voltage to a multiplication section. It is therefore possible to improve a pressure resistance performance against edge breakdown while suppressing crosstalk.
(1)

A photodetector including:
a first semiconductor substrate having a first surface and a second surface opposed to each other and including a pixel array section in which a plurality of pixels is arranged in array in an in-plane direction;
a light-receiving section that is provided inside the first semiconductor substrate for each of the pixels, and generates carriers corresponding to a received light amount by photoelectric conversion;
a multiplication section that is provided on the first surface for each of the pixels, and performs avalanche multiplication of the carriers generated in the light-receiving section;
an insulating layer stacked on the first surface, the insulating layer having one or a plurality of openings each provided at a predetermined position;
one or a plurality of polysilicon films that is provided on a side of the first surface with the insulating layer interposed between the first surface and the one or the plurality of polysilicon films along at least a border of the pixels that are adjacent to each other, and is electrically coupled to at least the light-receiving section through the one or the plurality of openings;
one or a plurality of first wirings provided along an outer shape of each of the pixels on the side of the first surface; and
one or a plurality of first connection wirings that is provided along the outer shape of each of the pixels on the side of the first surface, and electrically couples the one or the plurality of polysilicon films and the one or the plurality of first wirings to each other.
(2)

The photodetector according to (1), in which the one or the plurality of polysilicon films, the one or the plurality of first wirings, and the one or the plurality of first connection wirings are each formed continuously along the border of the pixels that are adjacent to each other.
(3)

The photodetector according to (1) or (2), in which
each of the plurality of pixels has a planar shape of a polygon, and
the one or the plurality of openings is provided at a corner of each of the plurality of pixels.
(4)

The photodetector according to any one of (1) to (3), in which
each of the plurality of pixels has a planar shape of a rectangle, and
the one or the plurality of polysilicon films and the light-receiving section are electrically coupled to each other through the one or the plurality of openings, the one or the plurality of openings being provided at each of four corners of each of the pixels.
(5)

The photodetector according to any one of (1) to (4), further including
a pixel separation section that is provided between the plurality of pixels adjacent to each other to extend from the first surface to the second surface, and electrically separates the plurality of adjacent pixels from each other.
(6)

The photodetector according to (5), further including
a plurality of first contact layers that is provided on the first surface along the pixel separation section, and is electrically coupled to the light-receiving section, in which
the one or the plurality of polysilicon films provided along the border between the adjacent pixels is electrically coupled to the light-receiving section through the plurality of first contact layers.
(7)

The photodetector according to (6), in which
each of the plurality of pixels has a planar shape of a polygon, and
the plurality of first contact layers is provided at a corner of each of the plurality of pixels.
(8)

The photodetector according to (6) or (7), in which
each of the plurality of pixels has a planar shape of a rectangle, and
the plurality of first contact layers is provided at each of four corners of each of the pixels.
(9)

The photodetector according to any one of (1) to (8), further including
a second contact layer provided at an approximate center of each of the pixels on the first surface and being electrically coupled to the multiplication section, in which
one of the one or the plurality of openings is provided on the second contact layer, and
one of the one or the plurality of polysilicon films is electrically coupled to the multiplication section through the second contact layer.
(10)

The photodetector according to any one of (1) to (9), further including:
a second contact layer that is provided at an approximate center of each of the pixels on the first surface, and is electrically coupled to the multiplication section;
a second wiring provided in a wiring layer, the wiring layer including the one or the plurality of first wirings; and
a second connection wiring that electrically couples the second contact layer and the second wiring to each other, in which
one of the one or the plurality of openings is provided on the second contact layer, and
the second connection wiring is directly electrically coupled to the second contact layer without through the one or the plurality of polysilicon films.
(11)

The photodetector according to any one of (1) to (10), further including:
a multilayer wiring layer including the one or the plurality of first wirings and the one or the plurality of first connection wirings; and
a second semiconductor substrate disposed between the first surface and the multilayer wiring layer, in which
the one or the plurality of first connection wirings penetrates the second semiconductor substrate.
(12)

The photodetector according to (11), in which the second semiconductor substrate is provided with a plurality of transistors that configures a readout circuit, the readout circuit outputting a pixel signal based on electric charge outputted from each of the plurality of pixels.
(13)

The photodetector according to any one of (1) to (12), in which the first connection wiring is formed using tungsten, aluminum, copper, cobalt, nickel, or titanium, or a silicon compound thereof.
(14)

A distance measurement apparatus including:
an optical system;
a photodetector; and
a signal processing circuit that calculates a distance to a measurement target from an output signal of the photodetector, in which
the photodetector includes
   a first semiconductor substrate having a first surface and a second surface opposed to each other and including a pixel array section in which a plurality of pixels is arranged in array in an in-plane direction,
   a light-receiving section that is provided inside the first semiconductor substrate for each of the pixels, and generates carriers corresponding to a received light amount by photoelectric conversion,
   a multiplication section that is provided on the first surface for each of the pixels, and performs avalanche multiplication of the carriers generated in the light-receiving section,
   an insulating layer stacked on the first surface, the insulating layer having one or a plurality of openings each provided at a predetermined position,
   one or a plurality of polysilicon films that is provided on a side of the first surface with the insulating layer interposed between the first surface and the one or the plurality of polysilicon films along at least a border of the pixels that are adjacent to each other, and is electrically coupled to at least the light-receiving section through the one or the plurality of openings,
   one or a plurality of first wirings provided along an outer shape of each of the pixels on the side of the first surface, and
   one or a plurality of first connection wirings that is provided along the outer shape of each of the pixels on the side of the first surface, and electrically couples the one or the plurality of polysilicon films and the one or the plurality of first wirings to each other.

The present application claims the benefit of Japanese Priority Patent Application JP2022-140195 filed with the Japan Patent Office on Sep. 2, 2022, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

What is claimed is:

1. A photodetector, comprising:
a first semiconductor substrate having a first surface and a second surface opposed to each other and including a pixel array section in which a plurality of pixels is arranged in array in an in-plane direction;
a light-receiving section that is provided inside the first semiconductor substrate for each of the pixels, and generates carriers corresponding to a received light amount by photoelectric conversion;
a multiplication section that is provided on the first surface for each of the pixels, and performs avalanche multiplication of the carriers generated in the light-receiving section;
an insulating layer stacked on the first surface, the insulating layer having one or a plurality of openings each provided at a predetermined position;
one or a plurality of polysilicon films that is provided on a side of the first surface with the insulating layer interposed between the first surface and the one or the plurality of polysilicon films along at least a border of the pixels that are adjacent to each other, and is electrically coupled to at least the light-receiving section through the one or the plurality of openings;
one or a plurality of first wirings provided along an outer shape of each of the pixels on the side of the first surface; and
one or a plurality of first connection wirings that is provided along the outer shape of each of the pixels on the side of the first surface, and electrically couples the one or the plurality of polysilicon films and the one or the plurality of first wirings to each other.

2. The photodetector according to claim 1, wherein the one or the plurality of polysilicon films, the one or the plurality of first wirings, and the one or the plurality of first connection wirings are each formed continuously along the border of the pixels that are adjacent to each other.

3. The photodetector according to claim 1, wherein
each of the plurality of pixels has a planar shape of a polygon, and
the one or the plurality of openings is provided at a corner of each of the plurality of pixels.

4. The photodetector according to claim 1, wherein
each of the plurality of pixels has a planar shape of a rectangle, and
the one or the plurality of polysilicon films and the light-receiving section are electrically coupled to each other through the one or the plurality of openings, the one or the plurality of openings being provided at each of four corners of each of the pixels.

5. The photodetector according to claim 1, further comprising
a pixel separation section that is provided between the plurality of pixels adjacent to each other to extend from the first surface to the second surface, and electrically separates the plurality of adjacent pixels from each other.

6. The photodetector according to claim 5, further comprising
a plurality of first contact layers that is provided on the first surface along the pixel separation section, and is electrically coupled to the light-receiving section, wherein
the one or the plurality of polysilicon films provided along the border between the adjacent pixels is electrically coupled to the light-receiving section through the plurality of first contact layers.

7. The photodetector according to claim 6, wherein
each of the plurality of pixels has a planar shape of a polygon, and
the plurality of first contact layers is provided at a corner of each of the plurality of pixels.

8. The photodetector according to claim 6, wherein
each of the plurality of pixels has a planar shape of a rectangle, and
the plurality of first contact layers is provided at each of four corners of each of the pixels.

9. The photodetector according to claim 1, further comprising
a second contact layer provided at an approximate center of each of the pixels on the first surface and being electrically coupled to the multiplication section, wherein
one of the one or the plurality of openings is provided on the second contact layer, and
one of the one or the plurality of polysilicon films is electrically coupled to the multiplication section through the second contact layer.

10. The photodetector according to claim 1, further comprising:
a second contact layer that is provided at an approximate center of each of the pixels on the first surface, and is electrically coupled to the multiplication section;
a second wiring provided in a wiring layer, the wiring layer including the one or the plurality of first wirings; and
a second connection wiring that electrically couples the second contact layer and the second wiring to each other, wherein
one of the one or the plurality of openings is provided on the second contact layer, and
the second connection wiring is directly electrically coupled to the second contact layer without through the one or the plurality of polysilicon films.

11. The photodetector according to claim 1, further comprising:
a multilayer wiring layer including the one or the plurality of first wirings and the one or the plurality of first connection wirings; and
a second semiconductor substrate disposed between the first surface and the multilayer wiring layer, wherein
the one or the plurality of first connection wirings penetrates the second semiconductor substrate.

12. The photodetector according to claim 11, wherein the second semiconductor substrate is provided with a plurality of transistors that configures a readout circuit, the readout circuit outputting a pixel signal based on electric charge outputted from each of the plurality of pixels.

13. The photodetector according to claim 1, wherein the first connection wiring is formed using tungsten, aluminum, copper, cobalt, nickel, or titanium, or a silicon compound thereof.

14. A distance measurement apparatus, comprising:
an optical system;
a photodetector; and
a signal processing circuit that calculates a distance to a measurement target from an output signal of the photodetector, wherein
the photodetector includes
a first semiconductor substrate having a first surface and a second surface opposed to each other and including a pixel array section in which a plurality of pixels is arranged in array in an in-plane direction,
a light-receiving section that is provided inside the first semiconductor substrate for each of the pixels, and generates carriers corresponding to a received light amount by photoelectric conversion,
a multiplication section that is provided on the first surface for each of the pixels, and performs avalanche multiplication of the carriers generated in the light-receiving section,
an insulating layer stacked on the first surface, the insulating layer having one or a plurality of openings each provided at a predetermined position,
one or a plurality of polysilicon films that is provided on a side of the first surface with the insulating layer interposed between the first surface and the one or the plurality
